(19) United States
(12) Patent Application Publication
(10) Pub. No.: US 2026/0123528 A1
(43) Pub. Date: Apr. 30, 2026

(54) SEMICONDUCTOR PACKAGE, SEMICONDUCTOR STRUCTURE, AND METHOD OF MANUFACTURING THE SAME

(71) Applicant: Taiwan Semiconductor Manufacturing Company, Ltd., Hsinchu (TW)

(72) Inventors: Chien-Hung Chen, Hsinchu (TW); Zih-Yi Wang, Hsinchu (TW); Jeng-Shian Tseng, Hsinchu (TW); Chang-Jung Hsueh, Taipei (TW); Chien-Li Kuo, Hsinchu City (TW)

(73) Assignee: Taiwan Semiconductor Manufacturing Company, Ltd., Hsinchu (TW)

(21) Appl. No.: 18/930,979

(22) Filed: Oct. 29, 2024

(51) Int. Cl. H01L 25/18; H01L 23/00; H01L 23/14; H01L 23/31; H01L 23/498; H01L 23/538; H01L 25/00; H10B 80/00

(52) U.S. Cl. CPC H10W 90/00; H10W 42/121; H10W 70/611; H10W 74/121; H10W 90/401; H10W 90/701; H10B 80/00; H10W 70/698

(57) ABSTRACT

A semiconductor package includes an interposer structure, a first semiconductor die, semiconductor dies, a first molding layer, and an encapsulant. The first semiconductor die and the second semiconductor dies are located over and electrically coupled to the interposer structure. The second semiconductor dies are laterally disposed adjacent to the first semiconductor die that includes memory dies and at least one dummy die. The first molding layer laterally surrounds the at least one dummy die. The encapsulant is disposed on the interposer structure and encapsulates the first semiconductor die and the second semiconductor dies. The first molding layer is disposed between at least one dummy die and the encapsulant. The dimensions of the memory die are substantially equal to the total dimensions of each of the at least one dummy die and the first molding layer.

### BACKGROUND

Semiconductor devices and integrated circuits used in a variety of electronic apparatus, such as cell phones and other mobile electronic equipment, are typically manufactured on a single semiconductor wafer. The dies of the wafer may be processed and packaged with other semiconductor devices or dies at the wafer level, and various technologies have been developed for the wafer level packaging (e.g., formation of redistribution circuit structure/layer) for ensuring the reliability of semiconductor packages.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 a schematic top view of a semiconductor package in accordance with some embodiments of the disclosure.

FIG. 2 is a schematic cross-sectional view of a semiconductor package along line A-A′ of FIG. 1 in accordance with some embodiments of the disclosure.

FIG. 3 is a schematic cross-sectional view of a dummy die package in accordance with some embodiments of the disclosure.

FIG. 4A is a schematic three-dimensional view of a dummy die package in accordance with some embodiments of the disclosure.

FIG. 4B is a schematic top view of the dummy die of FIG. 4A in accordance with some embodiments of the disclosure.

FIG. 5A is a schematic cross-sectional view of a memory die in accordance with some embodiments of the disclosure.

FIG. 5B is a schematic three-dimensional view of the memory die of FIG. 5A in accordance with some embodiments of the disclosure.

FIG. 6A through FIG. 6E are schematic cross-sectional views of various stages in a manufacturing method of a dummy die package in accordance with some embodiments of the disclosure.

FIG. 7 is a schematic cross-sectional view of a semiconductor package along A-A′ line of FIG. 1 in accordance with another embodiment of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for case of description to describe similar or different element(s) or feature(s) as illustrated in the figures, and may be used interchangeably depending on the order of the presence or the contexts of the description.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

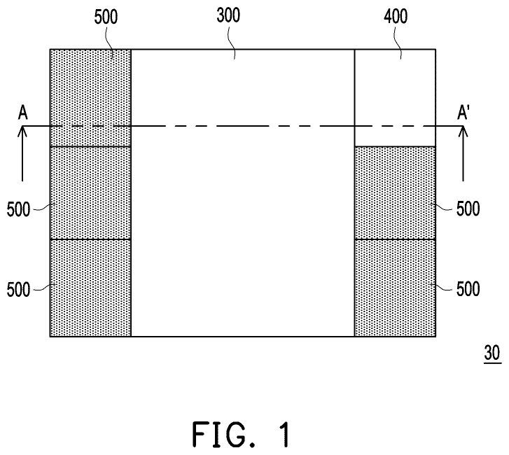

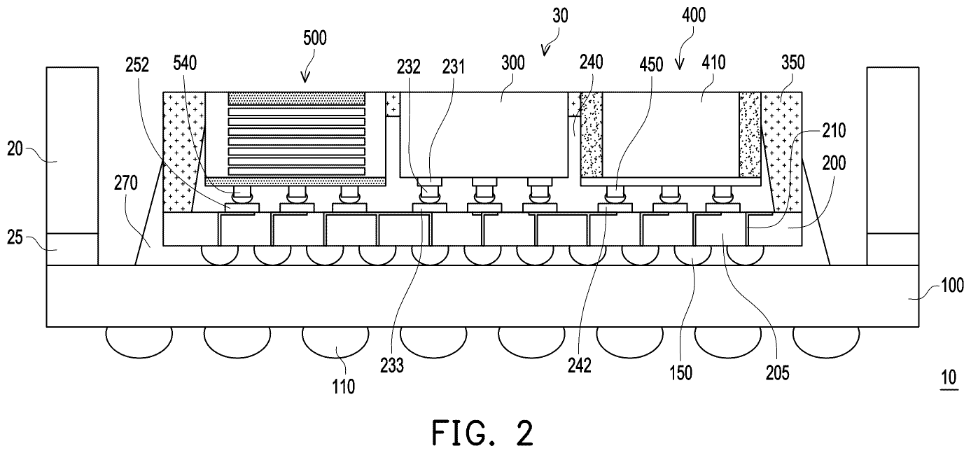

FIG. 1 a schematic top view of a semiconductor package 30 in accordance with some embodiments of the disclosure. FIG. 2 is a schematic cross-sectional view of the semiconductor package 30 along line A-A′ of FIG. 1 in accordance with some embodiments of the disclosure. Referring to FIG. 1 and FIG. 2, a semiconductor package 30 may include an interposer structure 200. In addition, the semiconductor package 30 includes a semiconductor die 300 (first semiconductor die) and a plurality of second semiconductor dies that may include memory dies 500 and a dummy die 410 located within the dummy die package 400. As shown in FIG. 1 and FIG. 2, the memory dies 500 and the dummy die package 400 are laterally disposed adjacent to and surround the semiconductor die 300. In some other embodiments not illustrated, more than one dummy die package 400 including the dummy die 410 may be disposed laterally adjacent to the semiconductor die 300 for reducing the numbers of the memory dies 500 required to be placed.

In some embodiments, the interposer structure 200 includes a core portion 205 formed therein. In some embodiments, the core portion 205 is a substrate such as a bulk semiconductor substrate, silicon on insulator (SOI) substrate, or a multi-layered semiconductor material substrate. The semiconductor material of the substrate (core portion 205) may be silicon, germanium, silicon germanium, silicon carbide, gallium arsenic, gallium phosphide, indium phosphide, indium arsenide, indium antimonide, GaAsP, AlInAs, AlGaAs, GaInAs, GaInP, GaInAsP, or combinations thereof. In some embodiments, the core portion 205 is doped or undoped.

In some embodiments, as shown in FIG. 2, the interposer structure 200 further includes the through vias 210 extend into the core portion 205 with a specific depth. In some embodiments, the through vias 210 are through-substrate vias. In some embodiments, the through vias 210 are through-silicon vias when the core portion 205 is a silicon substrate. In some embodiments, the through vias 210 are formed by forming holes or recesses in the core portion 205 and then filling the recesses with a conductive material. In some embodiments, the recesses are formed by, for example, etching, milling, laser drilling or the like. In some embodiments, the conductive material is formed by an electro-chemical plating process, chemical vapor deposition (CVD), atomic layer deposition (ALD) or physical vapor deposition (PVD), and the conductive material may include copper, tungsten, aluminum, silver, gold or a combination thereof. In certain embodiments, the interposer structure 200 may further include active or passive devices, such as transistors, capacitors, resistors, or diodes passive devices formed in the core portion 205.

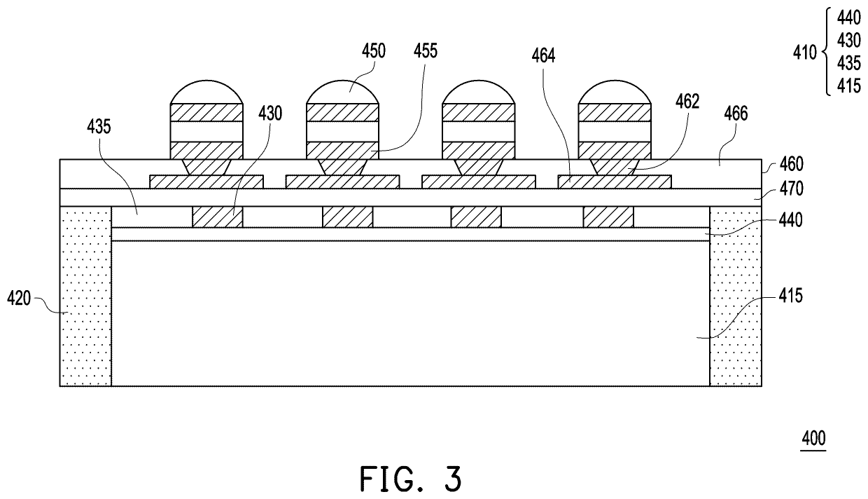

FIG. 3 a schematic cross-sectional view of a semiconductor package in accordance with some embodiments of the disclosure. Referring to FIG. 1 to FIG. 3, in some embodiments, the semiconductor package 30 may include a molding layer 420 laterally surrounding the dummy die 410 to form a dummy die package 400. In the current embodiment, the dimensions of the dummy die 410 may be modified through deposition of the molding layer 420 to form the dummy die package 400 and to match with the dimensions of the memory dies 500 for reducing the warpage of the interposer structure 200 where the semiconductor die 300, the dummy die package 400, and the memory die 500 are placed. In the present embodiment, the manufacturing process and yield of the semiconductor package 30 may be enhanced though matching the dimensions of the acquired dummy die 410 with the dimensions of the acquired memory dies 500 from different sources.

In some embodiments, the molding layer 420 includes a molding compound, a molding underfill, a resin (such as epoxy), or the like. In some alternative embodiments, the molding layer 420 includes nitride such as silicon nitride, oxide such as silicon oxide, PSG, BSG, BPSG, a combination thereof, or the like. In an alternative embodiment, the material of the molding layer 420 includes an organic material (e.g., epoxy, PI, PBO, or the like), or the mixture of inorganic and organic materials (e.g., the mixture of silicon oxide and epoxy, or the like). In some embodiments, the molding layer 420 may be formed by a molding process, such as a compression molding process. In some alternative embodiments, the molding layer 420 may be formed through suitable fabrication techniques such as CVD (e.g., high-density plasma chemical vapor deposition (HDPCVD) or PECVD). As illustrated in FIG. 2, the outermost surfaces of the semiconductor die 300, the memory dies 500, the dummy die 410, and the molding layer 420 surrounding the dummy die 410 are substantially leveled with and coplanar to each other.

In yet another alternative embodiment, referring to FIG. 3, a redistribution circuit layer 460 may be disposed over the dummy die 410 and the molding layer 420. In some embodiments, a buffer layer 470 may be disposed between the redistribution circuit layer 460 and the dummy die 410 to serve as buffer for a stress mismatch resulting from differences in the coefficients of thermal expansion (CTE) of the dummy die 410 and the redistribution circuit layer 460. In some embodiments, the buffer layer 470 may be formed of a polymer such as a polyimide, polybenzoxazole (PBO), benzocyclobutene (BCB), and the like.

In some embodiments, a plurality of conductive terminals 450 may be disposed on the redistribution circuit layer 460 and electrically connected thereto. In some embodiments, the conductive terminals 450 may be solder balls, ball grid array (BGA) balls, or controlled collapse chip connection (C4) bumps. Referring again to FIG. 3, in some embodiments, under bump metallurgy (UBM) pads 455 might be disposed between the conductive terminals 450 and the redistribution circuit layer 460. In some other embodiments not shown, more than one buffer layer (other than the buffer layer 470) might be disposed between the dummy die 410 and the redistribution circuit layer 460 for structural support and physical isolation of a conductive terminals 450 during packaging processes.

In some embodiments, the redistribution circuit layer 460 may include conductive pads 464 and the conductive vias 462 electrically connected to the conductive pads 464. Moreover, the redistribution circuit layer 460 may further include an inter-layer dielectric (ILD) layer surrounding the conductive vias 462 and the conductive pads 464.

In some embodiments, referring to FIG. 3, the dummy die 410 may include a silicon substrate 415, an interconnect structure 430, and a buffer layer 440. The buffer layer 440 is disposed between the interconnect structure 430 and the silicon substrate 415. In some embodiments, the dummy die 410 may further include a passivation layer 435 disposed on the buffer layer 440 and surrounding the interconnect structure 430. The passivation layer 435 may include one or more suitable dielectric materials such as silicon oxide, silicon nitride, combinations of these, or the like.

Referring back to FIG. 1, in some embodiments, the semiconductor die 300 has a surface area greater than that of the memory dies 500 and the dummy die package 400. Moreover, in some embodiments, the semiconductor dies 300, the memory dies 500, and the dummy die package 400 are of different sizes, including different surface areas and/or different thicknesses. In some embodiments, the semiconductor die 300 may be a logic die, including a central processing unit (CPU) die, graphics processing unit (GPU) die, system-on-a-chip (SoC) die, a microcontroller or the like. In some embodiments, the semiconductor die 300 may be a power management die, such as a power management integrated circuit (PMIC) die.

In some embodiments, the semiconductor die 300 may be referred to as a chip or an integrated circuit (IC). In some embodiments, the semiconductor dies 300 may include chip(s) of the same type or different types. For example, the semiconductor die 300 may include wireless and radio frequency (RF) chips. For example, in an alternative embodiment, the semiconductor dies 300 may be digital chips, analog chips, or mixed signal chips, such as application-specific integrated circuit (“ASIC”) chips, sensor chips, wireless and radio frequency (RF) chips, memory chips, logic chips, voltage regulator chips, or a combination thereof. In an alternative embodiment, the semiconductor die 300, one or all, may be referred to as a chip or a IC of combination-type. For example, the semiconductor die 300 may be a Wi-Fi chip simultaneously including both of a RF chip and a digital chip. The disclosure is not limited thereto.

In some embodiments, the memory dies 500 may include hybrid memory cube (HMC) dies or high bandwidth memory (HBM) dies. In some other embodiments, the memory dies 500 may include a memory device (e.g., a dynamic random-access memory (DRAM) die, static random-access memory (SRAM) die, a synchronous dynamic random-access memory (SDRAM), a NAND flash, etc.). The disclosure is not limited thereto, and the number, sizes and types of the semiconductor die 300, the dummy dies 400, and the memory dies 500 disposed on the core portion 205 may be appropriately adjusted based on product requirements.

Referring to FIG. 2, in some embodiments, the semiconductor package 30 may further include an encapsulant 350 encapsulating the interposer structure 200, the semiconductor die 300, the memory dies 500, and the dummy die package 400 that includes the dummy die 410. As shown in FIG. 2, the molding layer 420 is disposed between the dummy die 410 and the encapsulant 350. In some embodiments, materials of the encapsulant 350 may include polymers (such as epoxy resins, phenolic resins, silicon-containing resins, or other suitable resins), dielectric materials having low permittivity (Dk) and low loss tangent (Df) properties, or other suitable materials. In an alternative embodiment, the encapsulant 350 may include an acceptable insulating encapsulation material. In some embodiments, the encapsulant 350 may further include inorganic filler or inorganic compound (e.g. silica, clay, and so on) which can be added therein to optimize coefficient of thermal expansion (CTE) of the encapsulant 350. The disclosure is not limited thereto.

In some embodiment, the dimensions of each of the memory dies 500 may be substantially identical to the total dimensions of the dummy die 410 and the molding layer 420 surrounding the dummy die 410. In the present embodiment, the dimensions of the molding layer 420 surrounding the dummy die 410 may be adjusted corresponding to the dimensions of the memory dies 500 acquired to be packed within the semiconductor package 30 with the semiconductor die 300. Through modifying the total dimensions/volume of the acquired dummy die 410 by deposition of the molding layer 420 to match the dimensions/volume of the acquired memory dies 500, the warpage of the interposer structure 200 may be further controlled and reduced and thus enhance the yield of the semiconductor package 30.

Referring again to FIG. 2, in some embodiments, an underfill material 240 is formed between the semiconductor die 300, the dummy die package 400, the memory dies 500, and the interposer structure 200. In addition, the underfill material 240 is dispensed around the conductive terminals 232, 450, 540 and conductive pads 231, 233, 242, 252. In some embodiments, the underfill material 240 at least fills the gaps between the conductive terminals 232, 450, 540. As shown in FIG. 2, for example, the underfill material 240 is disposed on the interposer structure 200 and wraps sidewalls of the conductive terminals 232, 450, 540 to provide structural support and protection to the conductive terminals 232, 450, 540. In some embodiments, the underfill material 240 covers at least a part of the sidewalls of the semiconductor die 300, the dummy die package 400, and the memory dies 500 and exposes the respective back surfaces thereof.

However, the disclosure is not limited thereto. In an alternative embodiment (not shown), the underfill material 240 completely covers sidewalls of the semiconductor die 300, the dummy die package 400, and the memory dies 500. In a further alternative embodiment (not shown), the underfill material 240 completely covers the sidewalls of the semiconductor die 300, the dummy die package 400, and the memory dies 500 and accessibly exposes the back surfaces of the semiconductor die 300, the dummy die package 400, and the memory dies 500.

In one embodiment, the underfill material 240 may be formed by underfill dispensing or any other suitable method. In some embodiments, the underfill material 240 may be a molding compound including polymer material (e.g., epoxy, resin, and the like) cither with or without hardeners, fillers (e.g., silica filler, glass filler, aluminum oxide, silicon oxide, and the like), adhesion promoters, combinations thereof, and the like.

The semiconductor package 30 may be further disposed on a circuit substrate 100, and the conductive terminals 150 may be disposed between the interposer structure 200 and the circuit substrate 100. In some embodiments, the underfill material 270 may be disposed between the interposer structure 200 and the circuit substrate 100. Moreover, the underfill material 270 completely covers sidewalls of the conductive terminals 150. In some embodiments, the underfill material 270 may be a molding compound including polymer material (e.g., epoxy, resin, and the like) either with or without hardeners, fillers (e.g., silica filler, glass filler, aluminum oxide, silicon oxide, and the like), adhesion promoters, combinations thereof, and the like.

In some embodiments, a plurality of conductive terminals 110 may be disposed on a lower side of the circuit substrate 100 opposite to the other side where the semiconductor package 30 disposed to form a semiconductor structure 10 shown in FIG. 2. In one embodiment, the conductive terminals 110 are referred to as conductive connectors for connecting with another package or a circuit substrate (e.g. organic substrate such as PCB). In an alternative embodiment, the conductive terminals 110 are referred to as conductive terminals for inputting/outputting electric and/or power signals. In a further alternative embodiment, the conductive terminals 110 are referred to as conductive terminals for connecting with one or more than one semiconductor dies independently including active devices (e.g., transistors, diodes, etc.) and/or passive devices (e.g., capacitors, resistors, inductors, etc.), other components such as one or more than one integrated passive device (IPDs), or combinations thereof. The disclosure is not limited thereto. In some embodiments, the conductive terminals 110 may be solder balls, ball grid array (BGA) balls, or controlled collapse chip connection (C4) bumps.

Referring again to FIG. 2, a stiffener ring 20 may be further disposed along edges of the circuit substrate 100 though an adhesive layer 25. In some embodiments, the stiffener ring 40 may be composed of copper, but is not limited thereto.

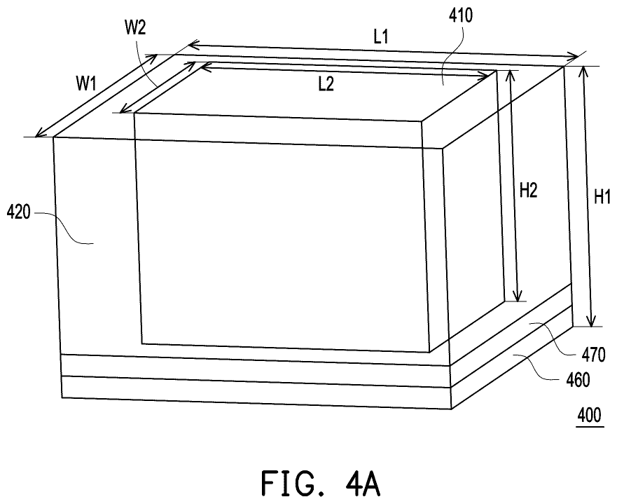

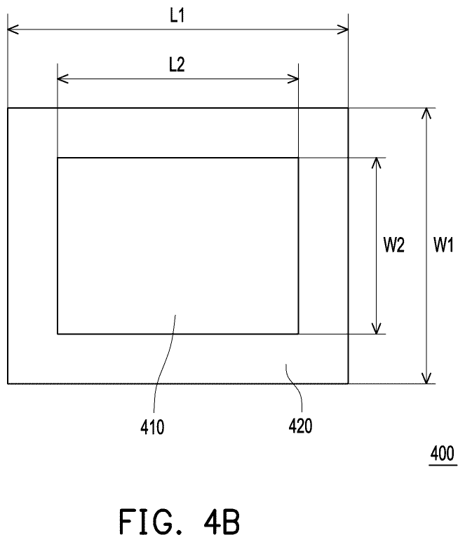

FIG. 4A is a schematic three-dimensional view of a dummy die package 400 in accordance with some embodiments of the disclosure. FIG. 4B is a schematic top view of the dummy die package 400 of FIG. 4A in accordance with some embodiments of the disclosure. Referring to FIG. 4A, in some embodiments, a length L2 of the dummy die 410 may be substantially between 5 mm to 14 mm. In some embodiments, a lateral width of the molding layer 420 surrounding the dummy die 410 from a single lateral side thereof may be substantially equal to or greater than 300 microns (μm). In some embodiments, a total length L1 of a dummy die package 400 including the dummy die 310 and the molding layer 420 as shown in FIG. 3 and FIG. 4 may be substantially between 7 mm to 15 mm. In some embodiments, a length ratio of the total length L1 of the dummy die package 400 including the molding layer 420 and the dummy die 410 to the length L2 of the dummy die 410 may be substantially between 1.02 to 1.18.

In some embodiments, the width W2 of the dummy die 410 may be substantially between 4 mm to 12 mm. In some embodiments, a total width W1 of the dummy die package 400 including the dummy die 410 and the molding layer 420 may be substantially between 5 mm to 13 mm. In some embodiments, a lateral width W1-W2 or L1-L2 of the molding layer 420 surrounding the dummy die 410 from a single lateral side thereof may be substantially greater or equal to 300 microns (μm). In some embodiment, a width ratio of the total width W1 of the dummy die package 400 including the molding layer 420 and the dummy die 410 to the width of the dummy die 410 may be substantially between 1.03 to 1.16.

In some embodiments, a vertical height H2 of the dummy die 410 may be substantially between 0.3 mm to 0.9 mm. In some embodiments, a total vertical height H2 of the dummy die package 400 including the dummy die 410 and the molding layer 420 may be substantially between 5 mm to 13 mm. In some embodiments, a vertical height ratio of the vertical height of the dummy die package 400 including the molding layer 420 and the dummy die 410 to the vertical height of the dummy die 410 may be substantially greater than 1.05.

Referring FIG. 2 to FIG. 5, in the current embodiments, through deposition of the molding layers 420 surrounding the dummy die 210 to form the dummy die package 400 for having the above configurational dimensions, the dimensions of the memory dies 500 may be identical to the dimensions of the dummy die package 400 including the dummy die 410 and the molding layer 420, and the memory dies 500 and the dummy package 400 are both disposed above the same interposer structure 200.

In yet another embodiment, the dimensions of the dummy die package 400 and the molding layer 420 may be further modified and differentiated from the above scopes of dimensions based on the dimensions of the dummy dies 410 and the memory dies 500 acquired from different fabrication sources for matching the overall dimensions of the dummy die package 400 and the memory dies 500 disposed on the same interposer structure 200 and thus for avoiding or reducing warpage thereof. In some embodiments, the warpage of the interposer structure 200 and the semiconductor package 30 might be reduced to at least less than 50 microns within heating temperatures substantially from 25 degrees Celsius to 225 degrees Celsius.

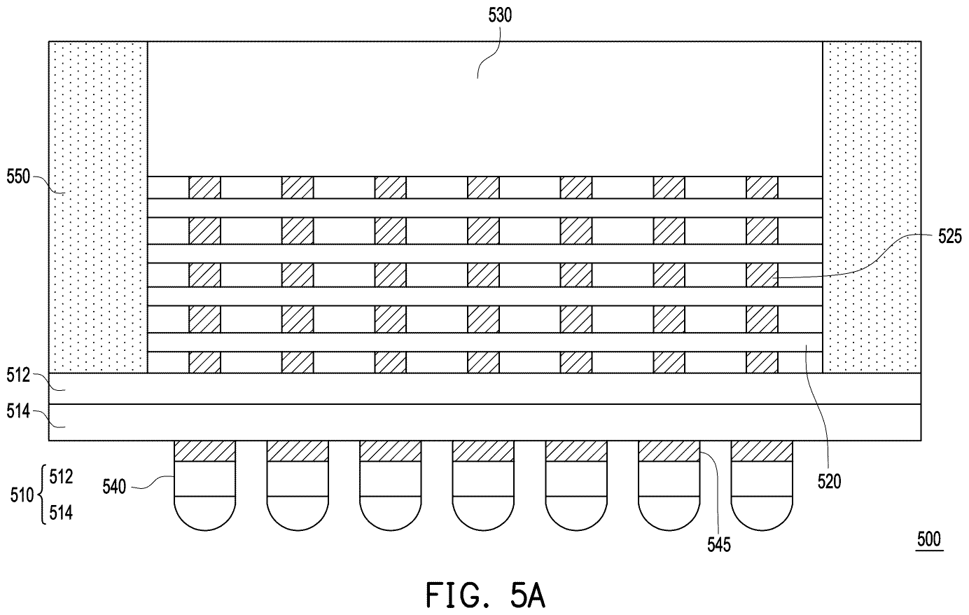

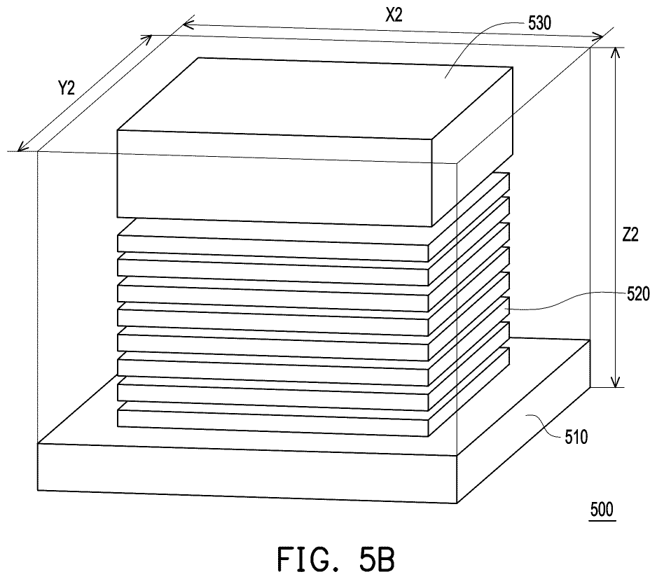

FIG. 5A is a schematic cross-sectional view of a memory die package in accordance with some embodiments of the disclosure. FIG. 5B is a schematic three-dimensional view of the memory die of FIG. 5A in accordance with some embodiments of the disclosure. Referring to FIG. 5A and FIG. 5B, each of the memory dies 500 includes a HBM 530 and a stacked dynamic RAM (DRAM) 520 including multi-level memory cells that communicate using through-silicon vias (TSV) 525. In some embodiments, referring to FIG. 5A and FIG. 5B, each of the memory dies 500 may include a carrier die 510 for disposing the HBM 530 and the stacked DRAM 520 thereon. In some embodiments, the carrier die 510 may be a logic die providing control functionality for the HBM 530 and the stacked DRAM 520. Referring to FIG. 5A, the carrier die 510 may further include a redistribution circuit layer 514 and a circuit substrate 512 stacked thereon. In some other embodiments, the memory dies 500 might further include multiple conductive terminals 540 electrically connected to the redistribution circuit layer 514 through the conductive pads 542. Referring to FIG. 5A, in some embodiments the UBM pads 545 may be disposed between the redistribution circuit layer 514 and the conductive terminals 540. In some embodiments, each of the memory dies 500 may further include a molding layer 550 disposed on the carrier die 510 and surrounding the HBM 530 and the stacked DRAM 520. As shown in FIG. 5A, the uppermost surface of the HBM 530 is exposed from the molding layer 550 and coplanar with the uppermost surface thereof. As shown in FIG. 2, the molding layer 550 may be disposed between the HBM 530, the stacked DRAM 520, and the encapsulant 350.

Referring to FIG. 4A and FIG. 5B, in some embodiments, the total length L1 of the dummy die package 400 may be tuned and modified through deposition of the molding layer 420 to substantially match a length X2 of the memory die 500. In addition, the total width W1 of the dummy die package 400 may be tuned through deposition of the molding layer 420 to substantially match a width Y2 of the memory die 500. Further, through a planarization process performed during manufacture of the semiconductor package 30, referring to FIG. 2, a vertical height of Z2 of the memory die 500 may be substantially identical to or may be substantially close to the total vertical height H1 of the dummy die package 400. As shown in FIG. 2, the uttermost surfaces of the semiconductor die 300, the dummy die package 400, and the memory dies 500 may be coplanar with each other and may be exposed from the encapsulant 350.

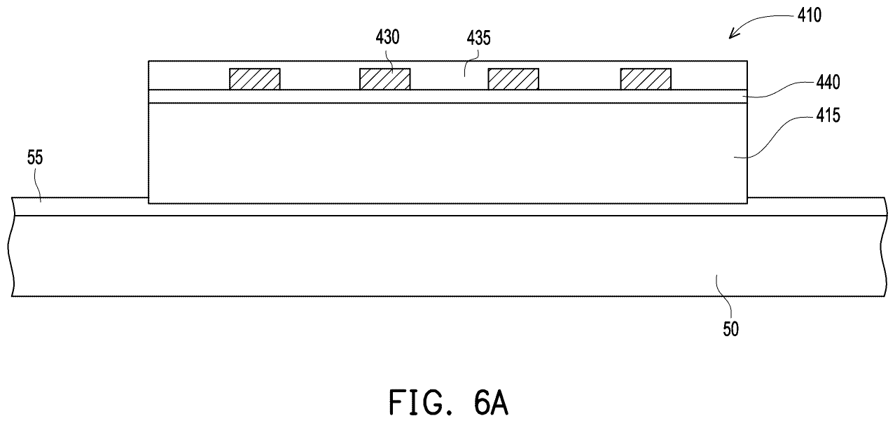

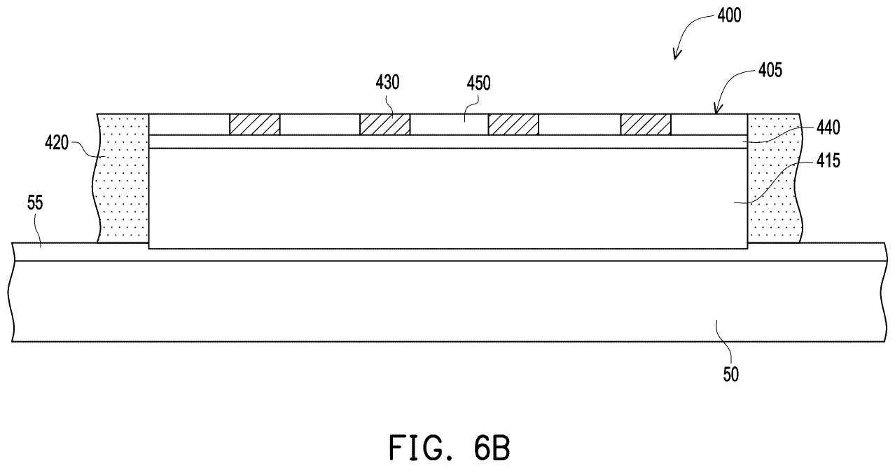

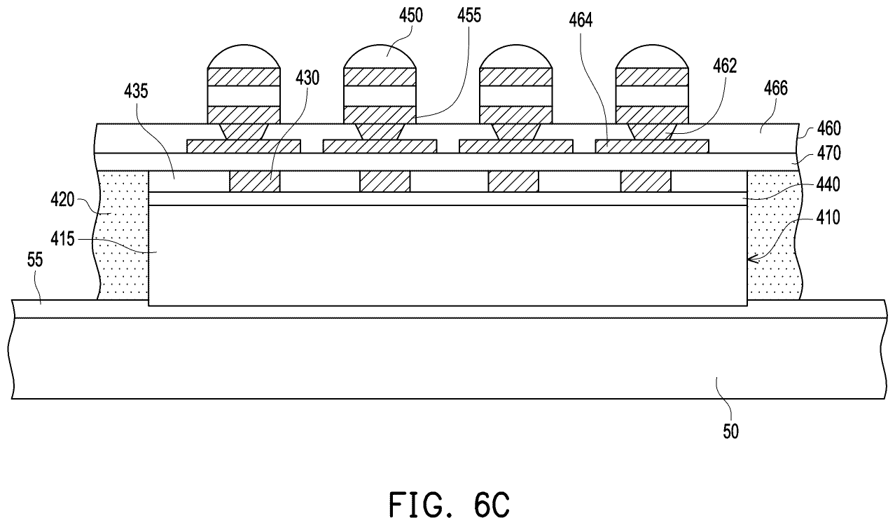

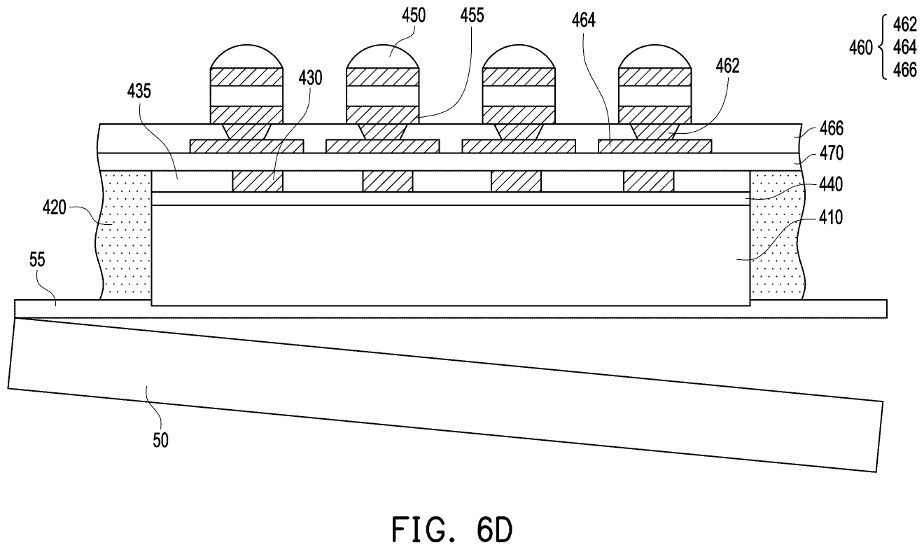

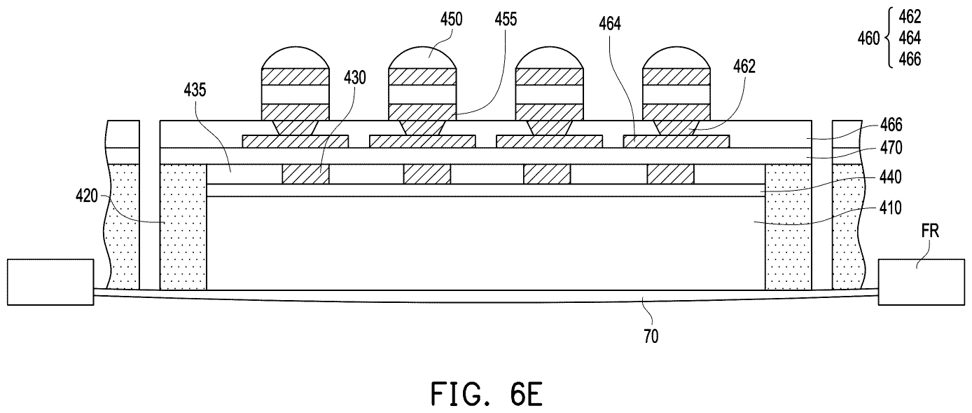

FIG. 6A through FIG. 6E are schematic cross-sectional views of various stages in a manufacturing method of a dummy die package 400 in accordance with some embodiments of the disclosure. Referring to FIG. 6A, a carrier 50 may be provided, and a dummy die 410 is attached to a carrier 50 through a die attach film 55. In some embodiments, the die attach film 55 may include an epoxy adhesive layer. In some other embodiments, the die attach film 55 may include an Ultra-Violet (UV) glue, a Light-to-Heat Conversion (LTHC) glue, or the like, although other types of adhesives may be used.

In some embodiments, a molding compound material may be deposited on the carrier 50 to cover an upper surface and sidewalls of the dummy die 410. Referring to FIG. 6B, a planarization process, including grinding or polishing, may be performed to partially remove the deposited molding compound material to form a molding layer 420 and to expose an upper surface 405 of the dummy die 410 from the molding layer 420.

In some alternative embodiments, the material of the molding layer 420 includes nitride such as silicon nitride, oxide such as silicon oxide, PSG, BSG, BPSG, a combination thereof, or the like. In yet alternative embodiments, the material of the molding layer 420 includes an organic material (e.g., epoxy, PI, PBO, or the like), or the mixture of inorganic and organic materials (e.g., the mixture of silicon oxide and epoxy, or the like). In some embodiments, the molding layer 420 may be formed by a molding process, such as a compression molding process. In some alternative embodiments, the molding layer 420 may be formed through suitable fabrication techniques such as CVD (e.g., high-density plasma chemical vapor deposition (HDPCVD) or PECVD). As illustrated in FIG. 6B, the surface 405 of the dummy die 410 is substantially leveled with and coplanar to a surface of the molding layer 420.

Referring to FIG. 6C, a buffer layer 470 may be formed over the dummy die 410. In some embodiments, forming materials of the buffer layer 470 include at least one of polyimide (PI), benzocyclobutene (BCB), polybenzoxazole (PBO), epoxy, silicone, acrylates, nano-filled phenolic resin or other suitable material. During the manufacturing process of the semiconductor package 400 shown in FIG. 3, the buffer layer 470 is cured under a heat treatment. For example, the heat treatment is performed in an oven filled with inert gas and at a temperature from approximately 220 degrees Celsius to approximately 380 degrees Celsius.

As shown in FIG. 6C, the redistribution circuit layer 460 is formed by sequentially forming one or more conductive pads 464, one or more conductive vias 462, and then covering the conductive pads 464 and the conductive vias 462 with the dielectric layers 466. In some embodiments, the material of the dielectric layers 466 includes polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the material of the dielectric layers 466 is formed by suitable fabrication techniques such as spin-on coating, chemical vapor deposition (CVD), plasma-enhanced chemical vapor deposition (PECVD) and the like. The disclosure is not limited thereto. In some embodiments, after deposition of the conductive pads 464, the conductive vias 462, and the dielectric layers 466, any excessive conductive material on the dielectric layer may be removed by using, for example, a chemical mechanical polishing process to expose outermost surfaces of the dielectric layers 466 and the conductive vias 462.

In some embodiments, the material of the conductive vias 462 is made of conductive materials formed by electroplating or deposition, such as aluminum, titanium, copper, nickel, tungsten, and/or alloys thereof, which may be patterned using a photolithography and etching process. In some embodiments, the conductive vias 462 may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, the materials of the conductive pads 464 may include copper, nickel, titanium, tungsten, or alloys thereof or the like, and may be formed by an electroplating process, for example. The number of conductive pads 464 are not limited in this disclosure and may be selected based on the design layout.

In addition, referring again to FIG. 6C, a plurality of conductive terminals 450 is formed on the UBM pads 455 and electrically connected to the redistribution circuit layer 460. In some embodiments, the conductive terminals 450 include lead-free solder balls, solder balls, ball grid array (BGA) balls, bumps, C4 bumps or micro bumps. In some embodiments, the conductive terminals 450 may include a conductive material such as solder, copper, aluminum, gold, nickel, silver, palladium, tin, or a combination thereof. In some embodiments, the conductive terminals 450 are formed by forming the solder paste on the redistribution circuit layer 460 by, for example, evaporation, electroplating, printing or solder transfer and then reflowed into the desired bump shapes. In some embodiments, the conductive terminals 450 are placed on the redistribution circuit layer 460 by ball placement or the like. In other embodiments, the conductive terminals 450 are formed by forming solder-free metal pillars (such as a copper pillar) by sputtering, printing, electroless or electro plating or CVD, and then forming a lead-free cap layer by plating on the metal pillars. The conductive terminals 450 may be used to bond to an external device or an additional electrical component. In some embodiments, the conductive terminals 450 are used to bond to a circuit substrate, a semiconductor substrate or a packaging substrate.

Referring to FIG. 6D, in some embodiments, after forming the redistribution circuit layer 460 and the conductive terminals 450 placed thereon, the carrier 50 is deboned and removed from back surfaces of the dummy die 410 and the molding layer 420. In some embodiments, residual of the die attach film 55 on the back surfaces of the dummy die 410 and the molding layer 420 may be removed and cleaned through, for example, a plasma cleaning process.

In some embodiments, referring to FIG. 6E, after removing the carrier 50 from the structure shown in FIG. 6D, the structure is then attached to a tape 70 (e.g., a dicing tape) supported by a frame FR for following dicing and singulation processes to form the dummy die package 400 as shown in FIG. 3.

In some embodiments, the dummy die package 400 is referred to as an integrated fan-out (InFO) like package. The dummy die package 400 may be further mounted with a circuit substrate, an interposer, an additional package, chips/dies or other electronic devices to form a stacked package structure such as a flip-chip package or a chip-on-wafer-on-substrate (CoWoS) package or a package-on-package (POP) structure through the conductive terminals 450.

Referring to FIG. 2, FIG. 3, and FIG. 6E, in some embodiments, the dummy die package 400 may be placed on the interposer substrate 200 with the multiple memory dies 500 and the semiconductor die 300 to form the semiconductor package 30. As shown in FIG. 2, the semiconductor package 30 may be further disposed on the circuit substrate 100 to form the semiconductor structure 10 that may be referred to as a CoWoS package.

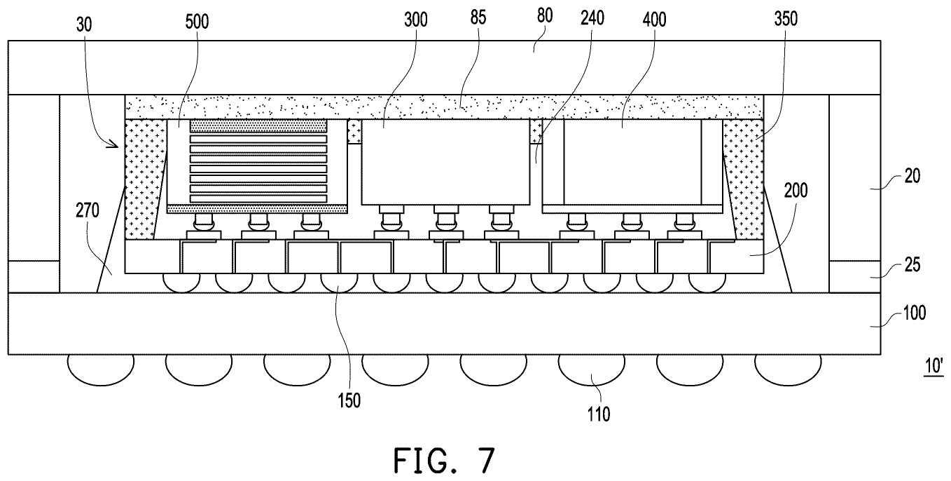

FIG. 7 is a schematic cross-sectional view of a semiconductor package 30 along AA′ line of FIG. 1 in accordance with another embodiment of the disclosure. In some embodiments, referring to FIG. 7, the difference between the embodiments shown in FIG. 2 and FIG. 7 is that a lid structure 80 may be further provided to the semiconductor structure 30 shown in FIG. 2 for enhancing the heat dissipation of the entire semiconductor package 30. Referring to FIG. 7, in some embodiments, the lid structure 80 may be attached to the back surfaces of the semiconductor die 300, the dummy die package 400, and the memory dies 500 through an adhesive layer 85. Hence, the semiconductor die 300, the dummy die package 400, and the memory dies 500 are located in between the lid structure 80 and the circuit substrate 100. The stiffener ring 20 may be also disposed between the lid structure 80 and the circuit substrate 100 through the adhesive layer 25 for securing the stiffener ring 20 on the circuit substrate 100. In some embodiments not shown, as the lid structure 80 is provided, a thermal interface metal is further attached on the back surfaces of the semiconductor die 300, the dummy die package 400, and the memory dies 500. In certain embodiments, the thermal interface metal is sandwiched in between the lid structure 80 and of the semiconductor die 300, the package 400, and the memory dies 500, and fills up the space therebetween to enhance the heat dissipation.

In accordance with some embodiments, a semiconductor package includes an interposer structure, a first semiconductor die, semiconductor dies, a first molding layer, and an encapsulant. The first semiconductor die and the second semiconductor dies are located over and electrically coupled to the interposer structure. The second semiconductor dies are laterally disposed adjacent to the first semiconductor die that includes memory dies and at least one dummy die. The first molding layer laterally surrounds the at least one dummy die. The encapsulant is disposed on the interposer structure and encapsulates the first semiconductor die and the second semiconductor dies. The first molding layer is disposed between at least one dummy die and the encapsulant. The dimensions of the memory die are substantially equal to the total dimensions of each of the at least one dummy die and the first molding layer.

In accordance with some embodiments, a semiconductor structure may include a circuit substrate and a semiconductor package. The semiconductor package is disposed on the circuit substrate. The semiconductor package includes an interposer structure, a plurality of memory dies, at least one dummy die, and a molding layer. The memory dies are disposed on the interposer structure. The at least one dummy die is disposed on the interposer structure and laterally disclosed adjacent to the memory dies. The molding layer laterally surrounds the at least one dummy die. The dimensions of each of the plurality of memory dies are substantially equal to total dimensions of each of the at least one dummy die and the molding layer.

In accordance with some embodiments, a method of manufacturing the semiconductor die includes providing a carrier. In addition, a dummy die is bonded to the carrier through a die attach film. A molding layer is formed on the carrier and laterally surrounds the dummy die. A redistribution circuit layer is formed over the dummy die and the molding layer. The through substrate vias are formed in the redistribution circuit layer. The conductive terminals are electrically connected to the redistribution circuit layer. The carrier is removed from the dummy die and the molding layer. The dummy die surrounded by the molding layer is disposed with memory dies to an interposer substate through the conductive terminals. The total dimensions of the dummy die and molding layer are substantially equal to dimensions of each of the memory dies.

What is claimed is:

1. A semiconductor package, comprising:
an interposer structure;
a first semiconductor die and a plurality of second semiconductor dies, located over and electrically coupled to the interposer structure, wherein the plurality of second semiconductor dies, laterally disposed adjacent to the first semiconductor die, comprises memory dies and at least one dummy die;
a first molding layer, laterally surrounding the at least one dummy die; and
an encapsulant, disposed on the interposer structure and encapsulating the first semiconductor die and the plurality of second semiconductor dies, wherein the first molding layer is disposed between the at least one dummy die and the encapsulant,
wherein dimensions of each of the memory dies are substantially equal to total dimensions of each of the at least one dummy die and the first molding layer.

2. The semiconductor package of claim 1, wherein a width ratio of a sum of a width of the first molding layer and a width of the each of the at least one dummy die to the width of the each of the at least one dummy die is between 1.03 to 1.16.

3. The semiconductor package of claim 2, wherein a lateral width of the first molding layer from a single side of the dummy die is equal to or greater than 300 microns.

4. The semiconductor package of claim 1, wherein a length ratio of a sum of a length of the first molding layer and a length of the each of the at least one dummy die to the length of the each of the at least one dummy die to is between 1.02 to 1.18.

5. The semiconductor package of claim 1, wherein a vertical height ratio of a sum of a vertical height of a first molding layer and a vertical height of the each of the at least one dummy die to the vertical height of the each of the at least one dummy die to is greater than 1.05.

6. The semiconductor package of claim 1, wherein the each of the memory dies comprises stacked memory cells and a second molding layer laterally surrounding the stacked memory cells, wherein the second molding layer is disposed between the stacked memory cells and the encapsulant.

7. The semiconductor package of claim 1, wherein the at least one dummy die comprises a silicon substrate and an interconnect structure, wherein the interconnect structure is disposed between the silicon substrate and the interposer structure.

8. The semiconductor package of claim 1, further comprising:
a redistribution circuit layer disposed over the at least one dummy die; and
a buffer layer disposed between the redistribution circuit layer and the at least one dummy die.

9. The semiconductor package of claim 1, wherein each of the memory dies comprises a high bandwidth memory (HBM).

10. A semiconductor structure, comprising
a circuit substrate; and
a semiconductor package, disposed on a circuit substrate, comprising
an interposer structure;
a plurality of memory dies, disposed on the interposer structure;
at least one dummy die, disposed on the interposer structure and laterally disposed adjacent to the plurality of memory dies; and
a molding layer, laterally surrounding the at least one dummy die, wherein total dimensions of each of the at least one dummy die and the molding layer are substantially equal to dimensions of each of the plurality of memory dies.

11. The semiconductor package of claim 10, wherein a width ratio of a sum of a width of the molding layer to a width of the each of the at least one dummy die to the width of the each of the at least one dummy die is between 1.03 to 1.16.

12. The semiconductor package of claim 10, wherein a lateral width of the first molding layer from a single side of the dummy die is equal to or greater than 300 microns.

13. The semiconductor package of claim 10, wherein a length ratio of a sum of a length of the molding layer and a length of the each of the at least one dummy die to the length of the each of the at least one dummy die is from 1.02 to 1.18.

14. The semiconductor structure of claim 10, wherein a vertical height ratio of a sum of a vertical height of the molding layer and a vertical height of the each of the at least one dummy die to the vertical height of the each of the at least one dummy die is greater than 1.05.

15. The semiconductor structure of claim 10, further comprising a stiffener ring attached to the circuit substrate and surrounding the semiconductor package.

16. The semiconductor structure of claim 10, further comprising a plurality of conductive terminals disposed between the semiconductor package and the circuit substrate.

17. The semiconductor structure of claim 16, further comprising an underfill material layer disposed between the plurality of conductive terminals and between the interposer structure and the circuit substrate.

18. A method of manufacturing a semiconductor package, comprising:
providing a carrier;
bonding a dummy die to the carrier through a die attach film;
forming a molding layer on the carrier and laterally surrounding the dummy die;
forming a redistribution circuit layer above the dummy die and the molding layer, wherein a plurality of through substrate vias is formed in the redistribution circuit layer;
forming a plurality of conductive terminals electrically connected to the redistribution circuit layer;
removing the carrier from the dummy die and the molding layer; and
disposing the dummy die surrounded by the molding layer with a plurality of memory dies to an interposer structure through the plurality of conductive terminals, wherein total dimensions of the dummy die and the molding layer are substantially equal to dimensions of each of the plurality of memory dies.

19. The method of claim 18, further comprising forming a buffer layer between the dummy die and the redistribution circuit layer.

20. The method of claim 18, further comprising dispensing an underfill material between the redistribution circuit layer and the interposer structure.
